(19) United States
(12) Patent Application Publication
(10) Pub. No.: US 2007/0200245 A1
(43) Pub. Date: Aug. 30, 2007

(54) Semiconductor device and pattern generating method

(75) Inventor: Masato Suga, Kawasaki (JP)

Correspondence Address: STAAS & HALSEY LLP, SUITE 700, 1201 NEW YORK AVENUE, N.W., WASHINGTON, DC, 20005, US

(73) Assignee: Fujitsu Limited, Kawasaki (JP)

(21) Appl. No.: 11/797,200

(22) Filed: May 1, 2007

Related U.S. Application Data
(62) Division of application No. 10/786,027, filed on Feb. 26, 2004, now abandoned.

(30) Foreign Application Priority Data
Mar. 27, 2003 (JP) 2003-088316

(51) Int. Cl. H01L 23/48

(52) U.S. Cl. 257/773

(57) ABSTRACT

Capacitance generated by a dummy pattern can be reduced without lowering wiring density by arranging the dummy pattern on one wiring layer in a manner responding to an actual pattern or the dummy pattern on the other wiring layer, whereby at least one of the following can be improved: distances between dummy patterns on different wiring layers, overlapped areas of dummy patterns, and such side length of the dummy pattern as opposed to the actual pattern on the same wiring layer.

### CROSS-REFERENCE TO RELATED APPLICATION(S)

This application is related to and is a divisional application of U.S. patent application Ser. No. 10/786,027, entitled SEMICONDUCTOR DEVICE AND PATTERN GENERATING METHOD, by Masato SUGA, filed Feb. 26, 2004 and incorporated by reference herein.

### BACKGROUND

1. Field of the Invention

The present invention is related to a semiconductor device and a pattern generation method, and more particularly, to arrangement of a wiring pattern being a dummy in a semiconductor device having a multilayered wiring.

2. Description of the Related Art

In recent years, along with increasing density and advancing integration, in semiconductor devices, a multilayered wiring structure is being employed, where a wiring (metal wiring) is divided by an interlayer insulating film to be formed of a plurality of layers. With the adoption of the multilayered wiring structure, wiring dimensions are substantially reduced to thereby prevent chip size from increasing and shorten the wiring length, so that delay in operation speed is restrained.

When fabricating a semiconductor device with a multilayered wiring, a process of CMP (Chemical Mechanical Polishing) is essential to diminish concavity and convexity generated by the wiring of a lower wiring layer to thereby flatten a surface of the interlayer insulating film, the CMP process being a technique that polishes the interlayer insulating film and the wiring so that level differences thereon are curbed. However, when there are large differences between wiring densities of (or a large distribution of wiring densities among) respective layers, a Step Height (erosion) or the like is caused to thereby bring trouble to the rest of the processes and resultant defective wiring of a disconnection or the like greatly affects the production yield of the wiring.

As one solution to this problem, there has been a technique that generates the dummy pattern in a region having no wiring pattern (wiring data) after the layout designing thereof (see Japanese Patent Application Laid-Open No. Hei 5-343540 as an example). FIG. 14 is a view showing an example arrangement of the dummy patterns in a prior art, where a part of any one layer of the plurality of layers composing the wiring pattern for an LSI is presented. In FIG. 14, WPA and WPB denote the wiring patterns (actual patterns) and DPA denotes the dummy pattern. With the dummy patterns generated as shown in FIG. 14, a minimum wiring density specified for the semiconductor device to be produced is ensured. This enables to reduce differences between the wiring densities in the semiconductor device so that improvement in flatness of the interlayer insulating film is attempted.

### SUMMARY

An object of the present invention is to enable to reduce wiring capacitance in a semiconductor device which is generated by a dummy pattern arranged thereon without lowering wiring density of the semiconductor device.

In the present invention, the semiconductor device having a plurality of wiring layers on which an actual pattern and the dummy pattern are arranged is provided, in which a position of a center point of the dummy pattern arranged on an (N+1)th wiring layer (N=natural number) is different from at least one of the following: a position of a center point of the dummy pattern arranged on an Nth wiring layer and a position on a center line of the actual pattern.

In another embodiment of the present invention, the semiconductor device having the plurality of wiring layers on which a dummy pattern and an actual pattern are arranged is provided, in which the dummy pattern having a rectangular shape is arranged by rotating a given turning angle in a direction in which the actual pattern extends.

According to the present invention, for the purpose of reducing capacitance generated by the dummy pattern without lowering wiring density of the semiconductor device, at least one of the following can be improved: distances between the dummy patterns on different wiring layers; overlapped areas of the dummy patterns; and such side length of the dummy pattern as opposed to the wiring pattern on the same wiring layer.

### BRIEF DESCRIPTION OF THE DRAWINGS

FIG. 1 is a view showing an example arrangement of dummy patterns according to a first embodiment;

FIGS. 2A and 2B are explanatory views for showing the basis of the first embodiment;

FIG. 3 is a view showing an example arrangement of dummy patterns according to a second embodiment;

FIGS. 4A and 4B are explanatory views for showing the basis of the second embodiment;

FIG. 5 is a view showing an example arrangement of dummy patterns according to a third embodiment;

FIG. 6 is an explanatory view for showing the basis of the third embodiment;

FIG. 7 is a view showing another example arrangement of the dummy patterns according to the third embodiment;

FIG. 8 is a view showing an example arrangement of dummy patterns according to a fourth embodiment;

FIG. 9 is an explanatory view for showing the basis of the fourth embodiment;

FIG. 10 is a view showing another example arrangement of the dummy patterns according to the fourth embodiment;

FIG. 11 is a view showing an example arrangement of dummy patterns according to a fifth embodiment;

FIG. 12 is a view showing another example arrangement of the dummy patterns according to the fifth embodiment;

FIG. 13 is a view showing still another example arrangement of the dummy patterns of the fifth embodiment;

FIG. 14 is a view showing an example arrangement of dummy patterns according to a prior art;

FIG. 15 is a flow chart showing a dummy pattern generation method according to the first embodiment;

FIG. 16 is a flow chart showing a dummy pattern generation method according to the second embodiment; and

FIG. 17 is a flow chart showing a dummy pattern generation method according to the third to fifth embodiments.

### DETAILED DESCRIPTION OF THE EMBODIMENTS

However, it is known that arranging a dummy pattern leads to capacitance increase and affects a total wire capacitance to a large degree. Also, a dummy pattern is conventionally arranged at random with the purposes of equalizing wiring density and so forth, so that it is difficult to estimate the capacitance to be generated by a dummy pattern arranged. Therefore, capacitance error due to capacitance generated by the dummy pattern possibly causes wrong estimate of wire delay time.

Hereinafter, embodiments of the present invention will be described with reference to the accompanying drawings. Note that example arrangements of dummy patterns shown in the drawings which are cited in the embodiments described below show a part of a wiring layer of a semiconductor device having a multilayered wiring structure such as an LSI and so forth. Further, in the description below, the wiring layer of the multilayered wiring which is placed on an Nth (N=any one natural number) layer from the lowest layer is referred to as “Nth wiring layer”.

### First Embodiment

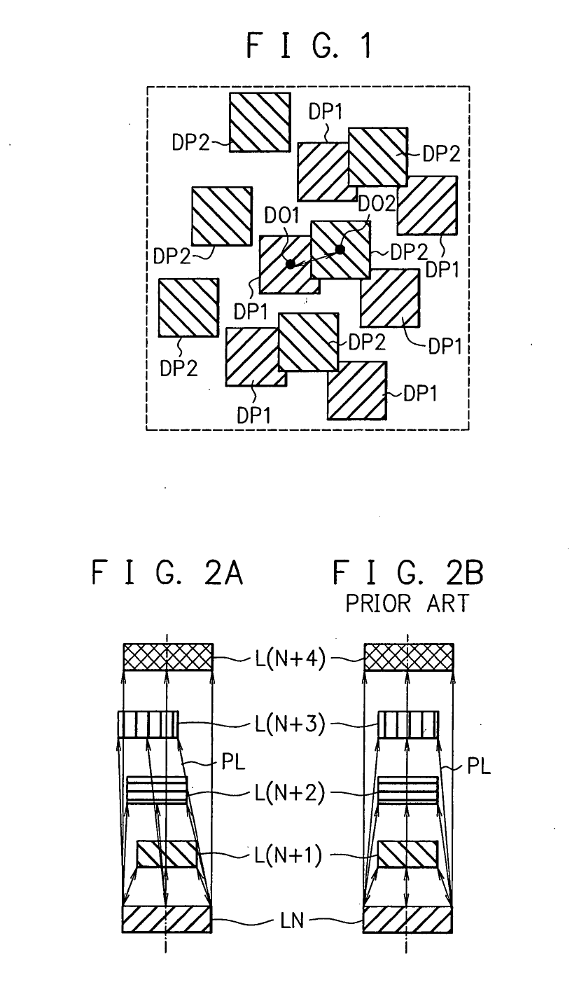

FIG. 1 is an explanatory view showing an example arrangement of dummy patterns according to a first embodiment of the present invention.

Referring to FIG. 1, DP1 denotes a dummy pattern arranged on an Nth wiring layer, and DP2 denotes the dummy pattern arranged on an (N+1)th wiring layer. As shown in FIG. 1, according to the first embodiment, the dummy patterns DP1 and DP2 are arranged so that a center point DO1 of the dummy pattern DP1 on the Nth wiring layer is placed at a position different from a center point DO2 of the dummy pattern DP2 on the (N+1)th wiring layer. (Note that these center points are those when seeing from a perpendicular viewpoint to the wiring layer.)

Here, the center point means for example a barycentric position when seeing from the perpendicular viewpoint to the wiring layer of the dummy patterns. In the case of a square or a rectangular dummy pattern, a diagonal cross thereof can be seen as the center point.

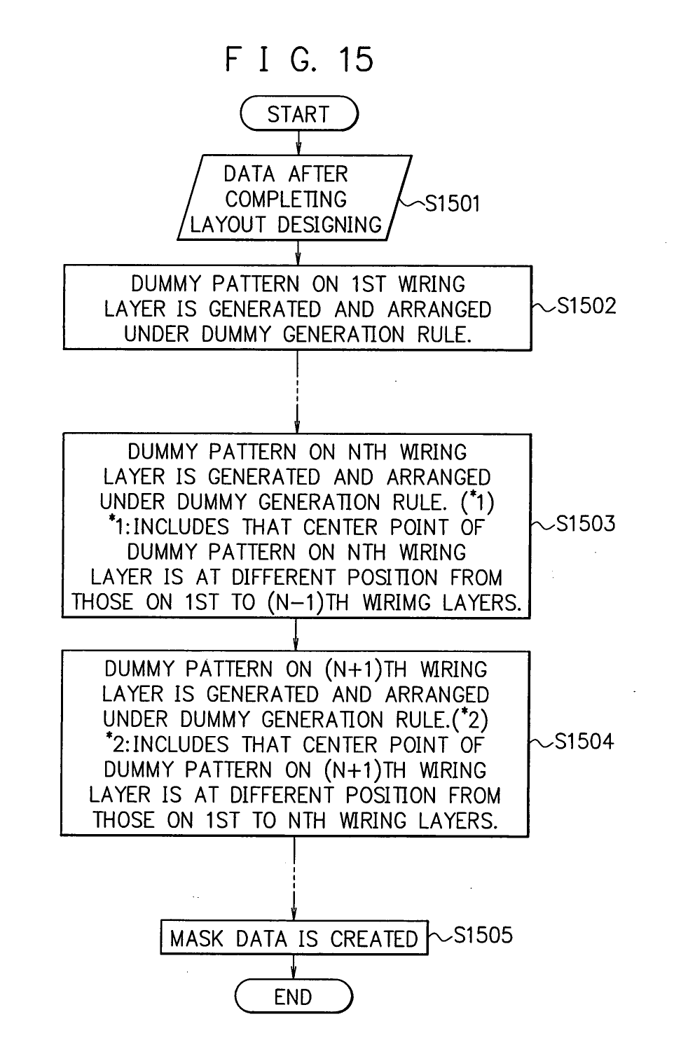

Referring to FIG. 15, a dummy pattern generation method so as to arrange as shown in FIG. 1 will be described.

First, there is provided a layout data (a design data for the LSI, for example, GDS data and so forth) which has completed an ordinary course of layout designing (S1501). With the layout data, the dummy pattern DP1 is generated and arranged within a generation region line under a dummy generation rule (S1502, S1503). Here, the generation region line is a periphery of a region within a chip, the region being previously defined for generating the dummy pattern and being other than an outer edge portion of the chip. The dummy pattern DP1 is arranged based on an original point from which the dummy pattern is generated (hereinafter referred to as “original point of generation”) in the region allowed to generate the dummy pattern DP1 at given intervals.

Next, the dummy pattern DP2 on the (N+1)th layer is generated and arranged within the generation region line under the dummy generation rule (S1504). The dummy generation rule on the dummy pattern DP2 includes that the center point DO1 of the dummy pattern DP1 on the Nth wiring layer is in any case placed at the position different from the center point DO2 of the dummy pattern DP2. This is possible by differentiating the original point of generation of the dummy pattern DP2 from that of the dummy pattern DP1. In this way, the dummy pattern DP2 is arranged with its center point DO2 being placed at the position different from the center point DO1 of the dummy pattern DP1, in the region allowed to generate the dummy pattern DP2 at given intervals.

Then, based on the layout data having the dummy pattern arranged on every wiring layer thereof, a mask data is created (S1505).

Note that two wiring layers of the Nth wiring layer and the (N+1)th wiring layer are cited as the example in the description mentioned above, however the example is also applicable to any and all wiring layers on which the dummy pattern is generated. From a different perspective, when having the multilayered wiring, one dummy pattern on one wiring layer is arranged with its center point being differently positioned from the center points of the other dummy patterns on the other wiring layers. In a case where 10 wiring layers are provided, the center point of each dummy pattern arranged on a first to a tenth layers are positioned so as not to overlap each other.

Similarly, in FIG. 1, a square dummy pattern is cited as the example of the dummy patterns DP1 and DP2, whereas, the dummy patterns DP1 and DP2 can be of any shape.

Subsequently, a basis of the first embodiment will be described with reference to FIGS. 2A and 2B.

FIG. 2A is a sectional view schematically showing physical relationship between dummy patterns and wiring patterns (actual patterns) arranged by adopting the first embodiment. FIG. 2B is the sectional view schematically showing physical relationship between the dummy patterns and the wiring patterns arranged in a conventional manner.

In FIGS. 2A and 2B, LN and L(N+4) denote wiring patterns arranged on the Nth wiring layer and an (N+4)th wiring layer respectively; and L(N+1), L(N+2), and L(N+3) denote dummy patterns arranged on the (N+1)th wiring layer, an (N+2)th wiring layer, and an (N+3)th wiring layer respectively. Also, in FIGS. 2A and 2B, each arrow indicates an electric flux line PL from the wiring pattern LN on the Nth wiring layer.

As shown in FIG. 2B, when dummy patterns L(N+1), L(N+2), and L(N+3) are arranged with their center points being overlapped with each other while being sandwiched between the lower wiring pattern LN and the upper wiring pattern L(N+4), each distance between dummy patterns L(N+1), L(N+2) and L(N+3) and the wiring patterns LN and L(N+4) on respective wiring layers are all minimized. Therefore, the electric flux lines pass through the shortest route, so that wiring capacitance is maximized.

On the contrary, as shown in FIG. 2A, when adopting the first embodiment, each distance between the dummy patterns L(N+1), L(N+2) and L(N+3) and the wiring patterns LN and L(N+4) on respective wiring layers becomes longer as compared to corresponding distances of the prior art in FIG. 2B. This prevents electrical charge from concentrating and the distributed electrical charge lowers capacitance as compared to the prior art.

As mentioned before, according to the first embodiment, capacitance generated by the dummy pattern can be reduced without lowering wiring density by making each distance between the dummy patterns of different wiring layers longer than that of the prior art. This is enabled by arranging each dummy pattern on each wiring layer in a manner that the center point thereof does not overlap with each other. As a result, effects caused by capacitance generated by the dummy pattern are alleviated, so that improvement in reliability and performance can be achieved in the semiconductor device such as of the LSI or the like.

### Second Embodiment

Hereinbelow, a second embodiment of the present invention will be described.

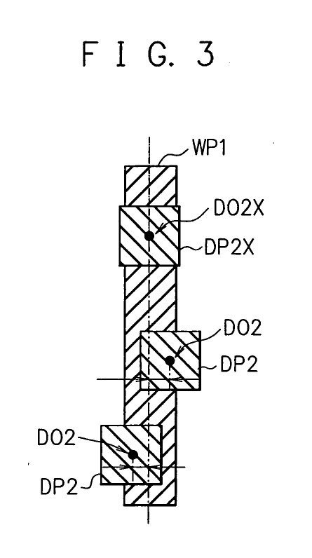

FIG. 3 is an explanatory view showing an example arrangement of dummy patterns according to the second embodiment of the present invention. In FIG. 3, WP1 denotes a wiring pattern (actual pattern) arranged on an Nth wiring layer and DP2 denotes the dummy pattern arranged on an (N+1)th wiring layer. As shown in FIG. 3, in the second embodiment, a center point DO2 of a dummy pattern DP2 is arranged with its center point DO2 not crossing over a center line of the wiring pattern WP1 (being a center line seeing from the direction to which the wiring pattern WP1 extends.) Therefore, a dummy pattern DP2X shown in FIG. 3 is in no case arranged since its center point DO2X is to cross over the center line of the wiring pattern WP1.

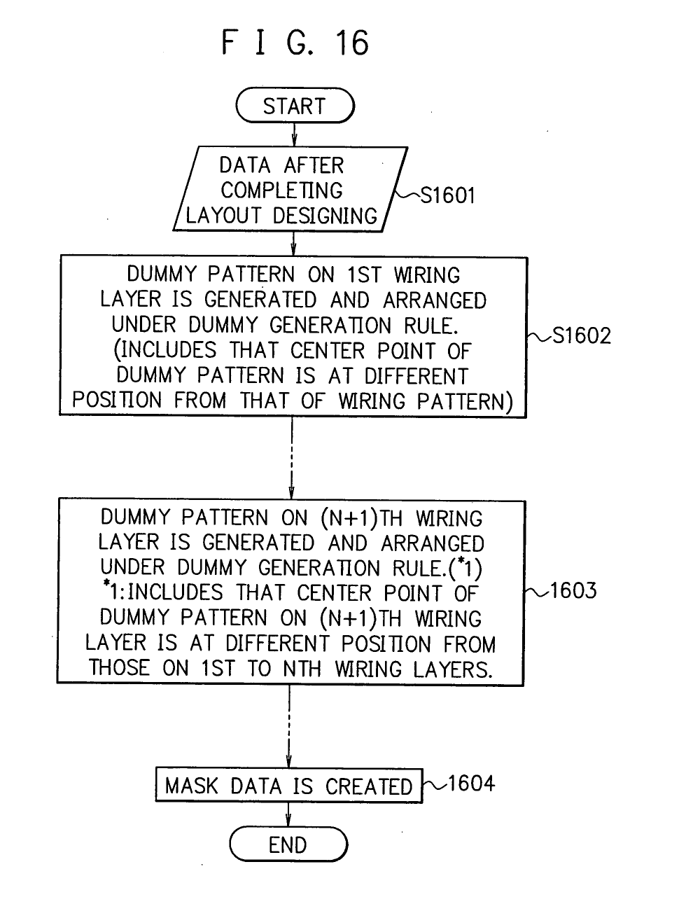

Referring to FIG. 16, a dummy pattern generation method so as to arrange as shown in FIG. 3 will be described.

There is provided a layout data which has completed an ordinary course of layout designing (S1601). With the layout data, the dummy pattern DP2 on an (N+1)th wiring layer is generated and arranged within a generation region line under a dummy generation rule (S1602, S1603). At the time, such a rule is included into the dummy generation rule that the center line of the wiring pattern WP1 must be placed at the position different from the center point DO2 of the dummy pattern DP2. By doing so, the dummy pattern DP2 is arranged with the center point DO2 thereof not crossing over the center line of the wiring pattern WP1, in the region allowed to generate the same at given intervals.

Then, based on such layout data as having the dummy pattern arranged on every wiring layer thereof, a mask data is created (S1604).

Note that the Nth wiring layer and the (N+1)th wiring layer are cited as the example in the description mentioned above, however, the example is also applicable to any and all wiring layers on which a dummy pattern is generated as in the case of the first embodiment. Similarly, the dummy pattern DP2 can be of any shape.

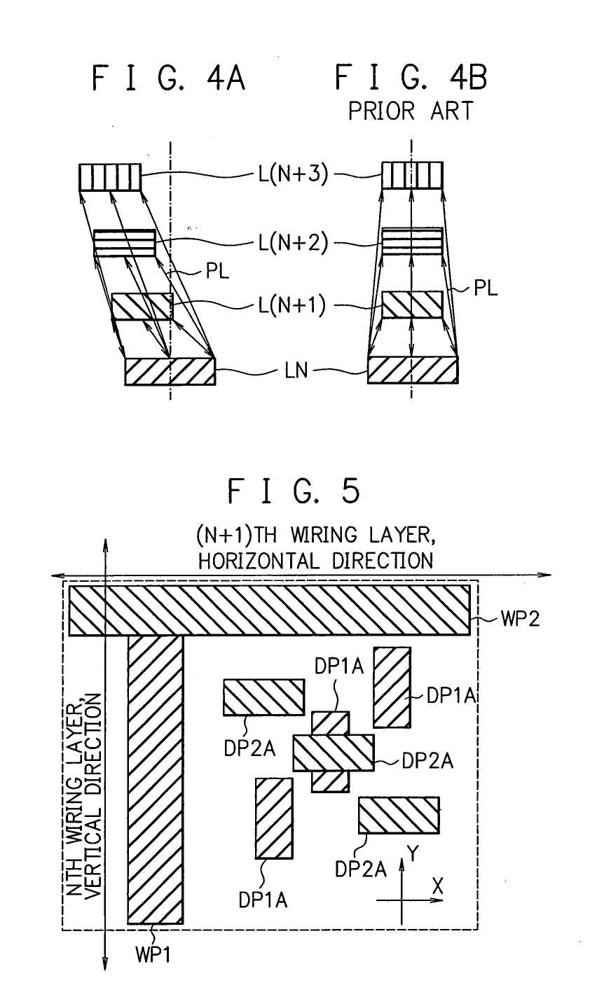

Subsequently, a basis of the second embodiment will be described with reference to FIGS. 4A and 4B.

FIG. 4A is a sectional view schematically showing physical relationship between dummy patterns and wiring patterns (actual patterns) arranged by adopting the second embodiment. FIG. 4B is a sectional view schematically showing physical relationship between the dummy patterns and the wiring patterns arranged in a conventional manner. As to LN, L(N+1), L(N+2), L(N+3), and PL, which will be used in the following, they are the same reference symbols as those in FIG. 2, so that the description will be omitted.

As shown in FIG. 4B, when the center points of dummy patterns L(N+1), L(N+2), and L(N+3) are on the center line of a wiring pattern LN, each distance between the dummy patterns and the wiring pattern all comes to the shortest. Accordingly, the electric flux lines pass through the shortest route so that capacitance is maximized. On the contrary, in the second embodiment, as shown in FIG. 4A, each distance between the dummy patterns and the wiring pattern is extended so that capacitance is reduced to lower than that of the prior art.

As mentioned before, according to the second embodiment, the capacitance generated by the dummy pattern can be reduced without lowering wiring density by arranging the center point of the dummy-pattern on each wiring layer so as not to cross over the center line of the wiring pattern.

### Third Embodiment

Hereinbelow, a third embodiment of the present invention will be described.

A multi-layered wiring in a semiconductor device such as of an LSI and so forth is commonly an orthogonal wiring. In the orthogonal wiring, as a direction in which the wiring extends, a horizontal (X) direction in a wiring layer surface and a vertical (Y) direction being orthogonal to the horizontal direction are appropriately chosen for each wiring layer. That is, the wirings on the wiring layers are made in the horizontal direction and in the vertical direction by turns for each wiring layer. Practically, when the extending direction of the wiring pattern on a first wiring layer is made horizontal (X), the extending direction of the wiring pattern on a second wiring layer is made vertical (Y) and that of the wiring pattern on a third wiring layer is made horizontal (X).

FIG. 5 is an explanatory view showing an example arrangement of dummy patterns according to the third embodiment of the present invention.

In FIG. 5, WP1 and WP2 denote wiring patterns (actual patterns) arranged on an Nth wiring layer and an (N+1)th wiring layer respectively. DP1A and DP2A denote dummy patterns arranged on the Nth wiring layer and the (N+1)th wiring layer respectively and each having a rectangular shape. As shown in FIG. 5, in the third embodiment, the dummy patterns DP1A and DP2A are arranged so that the long sides thereof have the same direction as the extending direction of the wiring patterns WP1 and WP2 being orthogonally wired on the same layer.

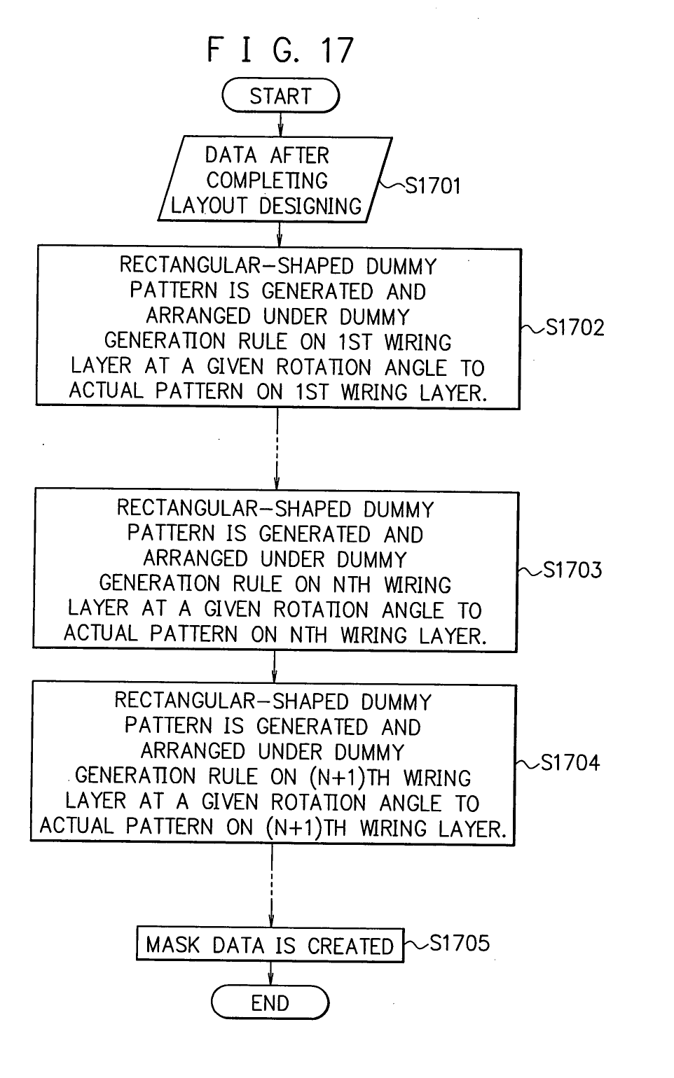

Referring to FIG. 17, a dummy pattern generation method so as to arrange as shown in FIG. 5 will be described.

There is provided a layout data which has completed an ordinary course of layout designing (S1701). With the layout data, dummy patterns DP1A on the Nth wiring layer are generated and arranged within a generation region line under a dummy generation rule (S1702, S1703). At this time, as one rule on the dummy pattern DP1A, such a rule is included into the dummy generation rule that the shape of the dummy pattern DP1A is made rectangle and that the long sides of the rectangular-shaped DP1A are in the same direction as the extending direction (vertical (Y) direction) of the wiring pattern WP1. By doing so, the dummy patterns DP1A are arranged with their long sides being in the same direction as the extending direction of the wiring pattern WP1, in the region allowed to generate the same at given intervals.

It is also included into the dummy generating rule on the other dummy layers that the shape of each dummy pattern is made rectangle and that the long sides of the rectangular-shaped dummy pattern are in the same direction as the extending direction of the wiring pattern defined for each wiring layer to thereby generate and arrange the dummy patterns on the other wiring layers under the dummy generating rule (S1704).

Then, based on the layout data having the dummy pattern arranged on every wiring layer thereof, a mask data is created (S1705).

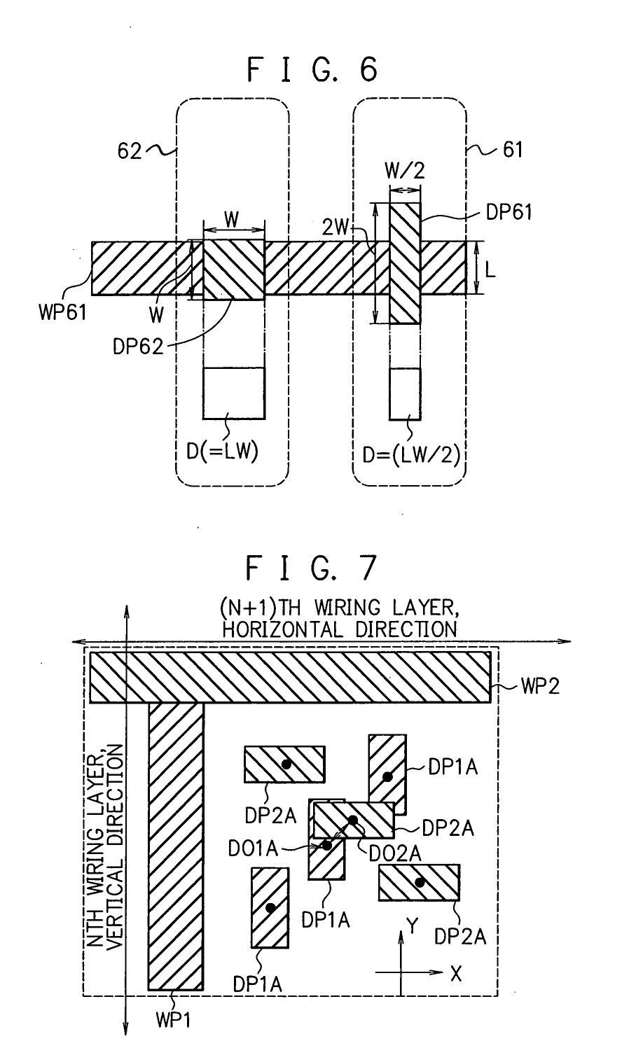

Subsequently, a basis of the third embodiment will be described with reference to FIG. 6.

FIG. 6 is an explanatory view for showing the basis of the third embodiment. Inside a dotted line 61, the example arrangement adopting the third embodiment is shown, and inside a dotted line 62, the example arrangement of the prior art is shown. In FIG. 6, WP61 is a wiring pattern arranged on the Nth wiring layer, and DP61 and DP62 are dummy patterns arranged on an (N+1)th wiring layer. Note that feature sizes of the dummy patterns DP61 and DP62 are 2W×(W/2) and W×W respectively, representing the same dimensions.

In the third embodiment, when there exists one wiring pattern on the Nth wiring layer, the wiring pattern on the Nth wiring layer is always orthogonal to any one of the dummy patterns on an (N−1)th wiring layer or the (N+1)th wiring layer, namely the lower wiring layer or the upper wiring layer of the Nth wiring layer. At the time, by decreasing an overlapped area of the dummy pattern on the Nth wiring layer and the dummy pattern on the adjacent wiring layer, capacitance generated by the dummy patterns falls. For example, in FIG. 6, the overlapping area D equals ½ (D=LW/2) of the example in the prior art (D=LW) to thereby reduce capacitance.

As mentioned before, according to the third embodiment, by arranging the dummy pattern having a rectangular shape in such a manner that the long sides thereof are arranged in the same direction as the extending direction of the wiring pattern orthogonally wired on the same wiring layer, the overlapped area of the dummy pattern and the dummy pattern on the different wiring layer is decreased without lowering wiring density so that the capacitance generated by the dummy pattern of the different wiring layer can be reduced.

Further, as shown in FIG. 7, the dummy patterns DP1A and DP2A may be arranged with their center points DO1A and DO2A being placed differently from each other for each wiring layer as in the case of the first embodiment mentioned before.

FIG. 7 is a view showing another example arrangement of dummy patterns of the third embodiment of the present invention. The dummy patterns DP1A and DP2A respectively on the Nth wiring layer and the (N+1)th wiring layer are arranged in such a manner that the long sides thereof are arranged in the same direction as the extending direction of the wiring layers WP1 and WP2 respectively on the same Nth wiring layer and the same (N+1)th wiring layer while differentiating the positions of the respective center points DO1A and DO2A of the dummy patterns DP1A and DP2A.

This is enabled by adding one rule of differentiating the center points of the dummy patterns from each other into the dummy generation rule of the third embodiment. Note that the dummy generation rule is applicable to every wiring layer on which the dummy pattern is generated.

By arranging the dummy pattern in the manner as shown in FIG. 7, the effect of the first embodiment mentioned before can be obtained in addition to the effect of the third embodiment. Furthermore, by adjusting moving amount of the center point of the dummy pattern, the overlapped area between the dummy patterns arranged on different wiring layers can be further decreased and whereby generated capacitance can be reduced as well.

Moreover, when adopting the second embodiment to the third embodiment, more effect can be obtained.

### Fourth Embodiment

Hereinbelow, a fourth embodiment of the present invention will be described.

In the third embodiment mentioned before, a dummy pattern having a rectangular shape is arranged with its long sides being in the same direction as the extending direction of a wiring pattern on the same wiring layer. In the fourth embodiment described below, the dummy pattern having the rectangular shape is arranged with its long sides being in the direction orthogonal to the extending direction of the wiring pattern on the same wiring layer.

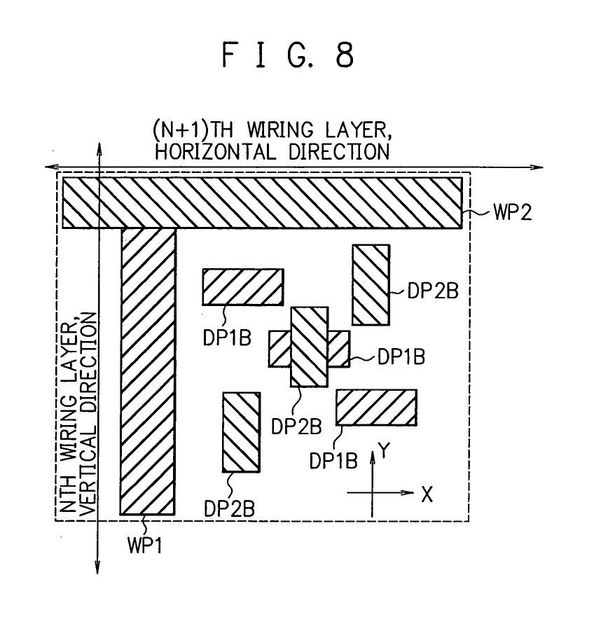

FIG. 8 is a view showing an example arrangement of the dummy patterns of the fourth embodiment of the present invention.

In FIG. 8, WP1 and WP2 denote the wiring patterns (actual patterns) respectively arranged on an Nth wiring layer and an (N+1)th wiring layer. DP1B and DP2B denote the dummy patterns each having a rectangular shape and arranged on the Nth wiring layer and the (N+1)th wiring layer respectively. As shown in FIG. 8, in the fourth embodiment, the dummy patterns DP1B and DP2B are arranged with their long sides being in the direction orthogonal to the extending direction of the wiring patterns WP1 and WP2 which are orthogonally wired on the same wiring pattern, respectively.

Incidentally, as for the dummy pattern generation method so as to arrange as shown in FIG. 8, the same method as described in the third embodiment is used by simply changing the direction of the long sides, so that the description will be omitted.

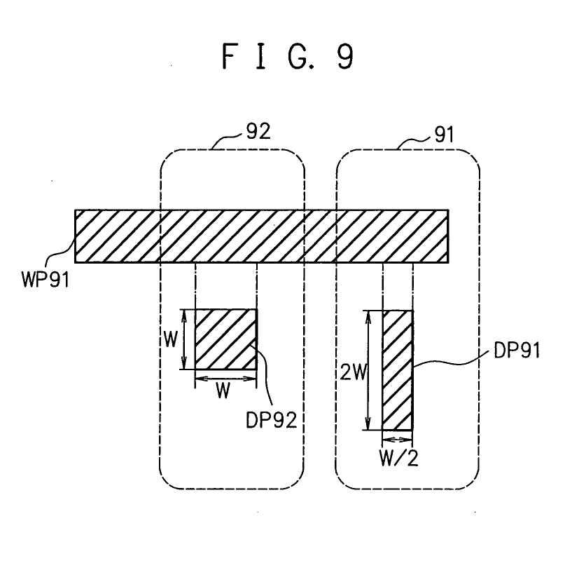

Subsequently, a basis of the fourth embodiment will be described with reference to FIG. 9.

FIG. 9 is an explanatory view for showing the basis of the fourth embodiment. Shown inside a dotted line 91 is the example adopting the fourth embodiment and shown inside a dotted line 92 is the example of the prior art. In FIG. 9, WP91 denotes a wiring pattern, and DP91 and DP92 denote dummy patterns, and all of them are arranged on the Nth wiring layer. Note that feature sizes of the dummy patterns DP91 and DP92 are 2W(W/2) and W×W respectively, representing the same dimensions.

On the same wiring layer, when such side length of the dummy pattern as opposed to the wiring pattern is shortened, the capacitance generated by the dummy pattern is reduced. In the fourth embodiment, for example as shown in FIG. 9, on the same wiring layer, such side of the dummy pattern as opposed to the wiring pattern comes to ½ (W/2) as compared to the prior art (W), so that capacitance is reduced.

As mentioned before, in the fourth embodiment, the dummy pattern having the rectangular shape is arranged with its long sides being in the direction orthogonal to the extending direction of the wiring pattern being the orthogonal wiring on the same wiring layer. This enables to reduce capacitance generated by the wiring pattern and the dummy pattern on the same wiring layer without lowering wiring density.

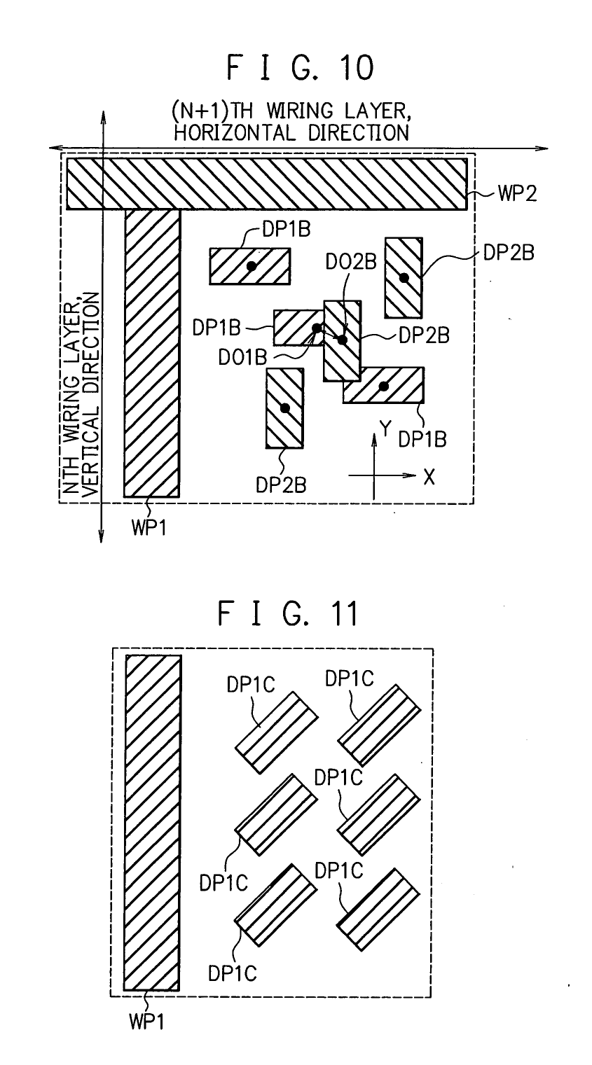

Further, as shown in FIG. 10, the dummy patterns DP1B and DP2B may be arranged with their center points DO1B and DO2B being placed differently for each wiring layer, where the effect of the first embodiment mentioned before can be obtained in addition to the effect of the fourth embodiment. Furthermore, adjustment of moving amount of the center point of the dummy pattern can reduce more capacitance generated by the dummy pattern.

### Fifth Embodiment

Hereinbelow, a fifth embodiment of the present invention will be described.

FIG. 11 is a view showing an example arrangement of dummy patterns of the fifth embodiment.

In FIG. 11, WP1 and DP1C denote a wiring pattern (actual pattern) and the dummy pattern of a rectangular shape respectively, both of which are arranged on an Nth wiring layer. As shown in FIG. 11, in the fifth embodiment, the rectangular-shaped dummy pattern DP1C is arranged by rotating a given angle to the extending direction of the wiring pattern WP1 on the same wiring layer so that the dummy pattern DP1C inclines toward the wiring pattern.

Note that the dummy pattern generation method so as to arrange as shown in FIG. 11 is the same as of the third and fourth embodiments mentioned before except that the dummy pattern is arranged here by rotating the given angle, so that the description will be omitted.

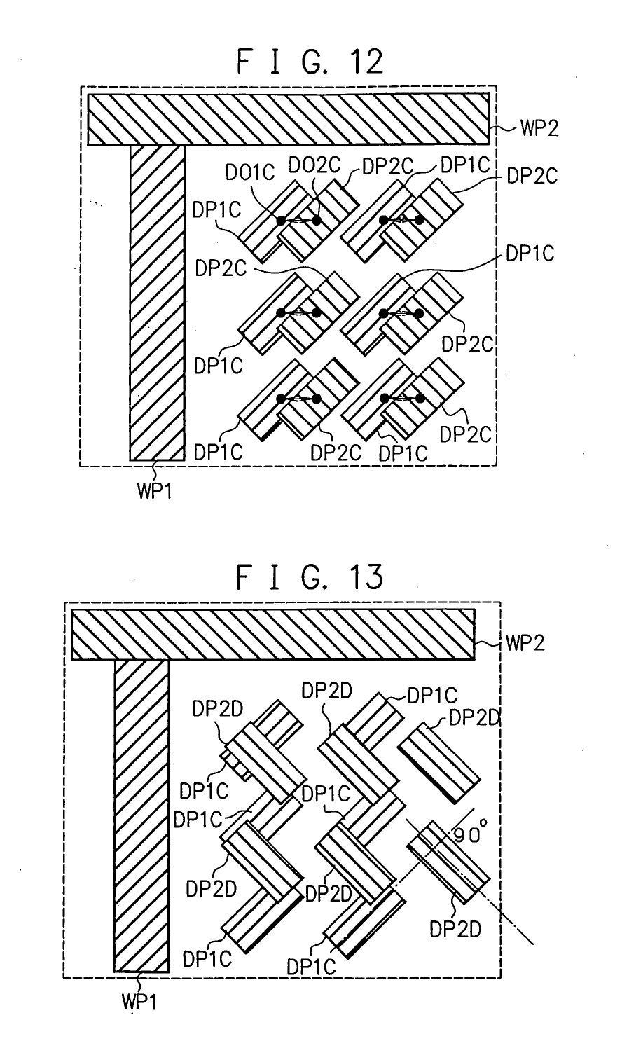

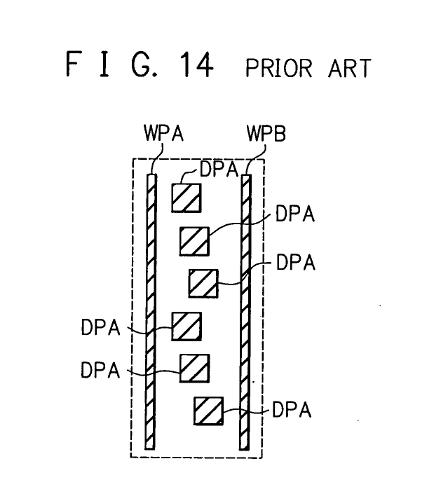

Incidentally, as shown in FIG. 12, the center point of each dummy pattern may be arranged differently for each wiring layer on which the dummy pattern is generated. For example, when arranging the dummy patterns DP1C and DP2C on the Nth wiring layer and an (N+1)th wiring layer respectively, the center point DO1C of the dummy patterns DP1C and the center point DO2C of the dummy pattern DP2C may be positioned differently from each other.

Further, as shown in FIG. 13, on the whole wiring layers on which the dummy pattern is generated, the dummy pattern may be arranged by rotating an angle of 90° to the dummy pattern on the adjacent wiring layer, so that, for example, the dummy pattern DP1C on the Nth wiring layer and the dummy pattern DP2D on the (N+1)th wiring layer are arranged orthogonally with each other. At the time, the dummy pattern arranged on the (N+1)th wiring layer and the dummy pattern arranged on an (N−1)th wiring layer are inclined in the same direction.

Here, in FIG. 12 and FIG. 13, WP1 and WP2 denote wiring patterns on the Nth wiring layer and the (N+1)th wiring layer respectively.

As mentioned before, according to the fifth embodiment, the dummy pattern having the rectangular shape is arranged by rotating the given angle to the extending direction of the wiring pattern. This enables to shorten the distance between the wiring pattern and the dummy pattern on the same wiring layer so that capacitance generated by the dummy pattern can be reduced.

Further, it is possible to obtain the effect of the first embodiment mentioned before by arranging the dummy patterns on the wiring layers with the center points thereof being differently positioned from each other. Furthermore, it is possible to reduce capacitance generated by the dummy patterns of different wiring layers by arranging the dummy pattern on one wiring layer orthogonally to the dummy pattern on the adjacent wiring layer.

As has been described above, according to the present invention, by appropriately arranging the dummy pattern in accordance with the actual pattern or the dummy pattern on the other wiring layer, at least one of the following improvement can be achieved without lowering wiring density: distances between dummy patterns on different wiring layers, overlapped areas of dummy patterns, and such side length of the dummy pattern as opposed to the actual pattern on the same wiring layer, to thereby enable to reduce capacitance generated by the dummy pattern. Consequently, the effect caused by capacitance generated by the dummy pattern can be alleviated and total capacitance including those generated by the dummy patterns can be reduced, so that improvement in reliability and performance can be achieved in the semiconductor device such as of the LSI or the like.

The present embodiments are to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

What is claimed is:

1. A semiconductor device having a plurality of wiring layers on which a dummy pattern and an actual pattern are arranged,
wherein a position of a center point of said dummy pattern arranged on an (N+1)th wiring layer (N=natural number) is different from at least one of followings: a position of a center point of said dummy pattern arranged on an Nth wiring layer, and a position on a center line of said actual pattern.

2. The semiconductor device according to claim 1,
wherein positions of center points of said dummy patterns on said plurality of wiring layers vary for respective wiring layers.

3. A semiconductor device having a plurality of wiring layers on which a dummy pattern and an actual pattern are arranged,
wherein said dummy pattern has a rectangular shape and is arranged by rotating a given angle in a direction in which said actual pattern extends.

4. The semiconductor device according to claim 3,
wherein longer sides of said dummy pattern extend perpendicularly to the direction in which said actual pattern extends.

5. The semiconductor device according to claim 4,
wherein said actual pattern is perpendicularly wired.

6. The semiconductor device according to claim 3,
wherein positions of center points of said dummy patterns of said plurality of wiring layers vary for respective wiring layers and respective longer sides of said dummy patterns on different wiring layers extend parallel to each other.

7. The semiconductor device according to claim 3,
wherein respective longer sides of said dummy patterns on adjacent wiring layers extend perpendicularly to each other.

8. A pattern generation method for a semiconductor device,
wherein a position of a center point of said dummy pattern arranged on an (N+1)th wiring layer (N=natural number) is made different from at least one of followings: a position of a center point of said dummy pattern arranged on an Nth wiring layer, and a position on a center line of an actual pattern.

9. A pattern generation method for a semiconductor device,
wherein a dummy pattern on an (N+1)th wiring layer is arranged so that a center point thereof does not overlap center points of dummy patterns on first to Nth wiring layers (N=natural number).

10. A pattern generation method for a semiconductor device,
wherein a dummy pattern having a rectangular shape is arranged by rotating a given angle to an extending direction of an actual pattern on the same wiring layer on which the actual pattern is arranged.

11. The pattern generation method for a semiconductor device according to claim 10,
wherein the dummy pattern is arranged so that longer sides thereof extend in the same direction as the actual pattern, which is perpendicularly wired, extends.

12. The pattern generation method for a semiconductor device according to claim 10,
wherein the dummy pattern is arranged so that the longer sides thereof extend perpendicularly to a direction in which the actual pattern being perpendicularly wired extends.

13. The pattern generation method for a semiconductor device according to claim 10,
wherein the dummy pattern is arranged so that long sides thereof extend perpendicularly to that of the dummy patterns on the adjacent wiring layers.

14. The semiconductor device according to claim 3,
wherein positions of center points of said dummy patterns of said plurality of wiring layers vary for respective wiring layers.
